(19) United States
(12) Patent Application Publication
(10) Pub. No.: US 2025/0277853 A1
(43) Pub. Date: Sep. 4, 2025

(54) EFUSE IMPLEMENTATIONS ON SAFETY CRITICAL INTEGRATED CIRCUITS

(71) Applicant: Rivian IP Holdings, LLC, Irvine, CA (US)

(72) Inventors: Vasant Kumar EASWARAN, Frisco, TX (US); Ting LU, Austin, TX (US); Gunasekaran RAMASAMY, San Ramon, CA (US)

(21) Appl. No.: 19/038,556

(22) Filed: Jan. 27, 2025

Related U.S. Application Data
(60) Provisional application No. 63/560,610, filed on Mar. 1, 2024.

(51) Int. Cl. G01R 31/3187

(52) U.S. Cl. CPC G01R 31/3187

(57) ABSTRACT

Aspects of the disclosure relate to an integrated circuit that operates an approach for functionally safe processing using hardware integrity checks of one or more electronic components. An apparatus may use CRC checksum computation on eFuses. In addition, safety mechanisms, such as triple modular redundancy, hardware logic, memory built-in-self-test, or software built-in-self-test may be used in conjunction to ensure integrity of the eFuses.

### CROSS REFERENCE TO RELATED APPLICATION(S)

The present application claims the benefit of U.S. Provisional Application No. 63/560,610, entitled “EFUSE IMPLEMENTATIONS ON SAFETY CRITICAL INTEGRATED CIRCUITS” filed on Mar. 1, 2024, the entirety of which is incorporated herein for reference.

### INTRODUCTION

Automotive Safety Integrity Level (ASIL) is a risk classification system defined by the ISO 26262 standard for the functional safety of road vehicles. ASIL classifies hazards in one of four levels, denoted as A through D, with a fifth additional level for non-hazardous systems or components. ASIL D represents the highest level of risk, while ASIL A represents the lowest risk level.

The standard defines functional safety as “the absence of unreasonable risk due to hazards caused by malfunctioning behavior of electrical or electronic systems.” ASILs establish safety requirements—based on the probability and acceptability of harm—for automotive components to be compliant with ISO 26262.

Systems that include vehicle brakes may require an ASIL-D grade—the highest rigor applied to safety assurance—because of the significant risks associated with their failure. ASIL-B examples are headlights and brake lights, while ASIL C may be for systems that include cruise control. Rear lights are example lights that may be classified with an ASIL-A grade.

Aspects of the subject technology can help to improve the overall cost, reliability, and efficiency of circuits or other electronic components.

### SUMMARY

The present description is generally directed to a configuration of an electronic fuse (eFuse) implementation that may be associated with one or more safety critical integrated circuits. The disclosed subject matter may use safety mechanisms with CRC checksum computation on data associated with one or more eFuses. In addition, safety mechanisms used here may include triple modular redundancy (TMR), HW logic, memory built-in-self-test (MBIST) or software BIST are also used in conjunction to ensure integrity of the eFuses.

In accordance with one or more aspects of the disclosure, one or more apparatuses may have mechanisms for functionally safe processing using hardware integrity checks of one or more electronic components. An eFuse block of an integrated circuit may include a first eFuse and a second eFuse. Faults with regard to the eFuse block may be assessed based on cyclic redundancy check (CRC) integrity checks during boot-up or while in mission mode. In addition, TMR, HW logic, memory BIST, or software BIST may be used in conjunction with CRC to help ensure integrity of the eFuses.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates an example eFuse implementation for fault monitoring of one or more components.

FIG. 2 illustrates components of an eFuse implementation for fault monitoring.

FIG. 3 illustrates an example sequence diagram associated with for fault monitoring of one or more components.

FIG. 4 illustrates an example method for performing hardware integrity checks in electronic components.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form in order to avoid obscuring the concepts of the subject technology.

In computing, an eFuse is a microscopic fuse put into a computer chip and is an active circuit protection device with an integrated field-effect transistor (FET) used to limit currents, voltages to safe levels during fault conditions. There may be various uses of eFuses that are safety critical, some of which are as follows: Joint Test Action Group identification (JTAG ID), Die ID, binding identity for secure authentication (e.g., binding ID), sensor trim data (e.g., PVT—process, voltage, and temperature, temperature, oscillators, etc.), or memory repair information. As disclosed, with reference to sensor trim data, for example, the eFuses may be used to drive certain sensor inputs that then ensure the sensor works correctly. Similarly, with reference to memory repair, the eFuses may be used to drive certain memory inputs that then ensure the memory works correctly. If any of the these were to have defects, it may go undetected and may cause incorrect inferences and safety goal violations at the system level.

ASIL (Automotive Safety Integrity Level) rated SoCs typically have use of eFuses on the SoC which are used in safety critical operations like memory repair or configuring trim settings, which may need to meet the highest ASIL integrity levels. There may be multiple ways to achieve different levels of ASIL. In a first implementation, there may be two eFuses implemented in order to meet reliability, while four eFuses may be implemented in order to meet higher level safety requirements (e.g., ASIL D).

Duplication and comparison of fuses, such as the use of four eFuses, may be implemented for redundancy and safety. Duplicating fuses and comparing them to detect these faults may be an expensive approach when the number of fuses grows to a significant number. There may be other approaches that may accomplish the desired ASIL rating while minimizing duplication. A first approach may include using precomputed CRC checksums of the eFuses, which may be stored along with the eFuses. The precomputed CRC checksums may then be re-verified through a hardware CRC checker before loading them to on-chip memory for accesses thereafter. In an example, and as further disclosed herein, an implementation may include the use of CRC checksum, instead of adding additional eFuses. In addition to the first approach, logic built-in-self-test (LBIST), memory BIST (MBIST), software BIST, or triple modular redundancy (TMR) may be used to determine that there are no hardware failures post the eFuses being used by the respective hardware blocks and therefore may help achieve higher integrity (e.g., ASIL D) for certain blocks. The number of eFuses that are implemented may be minimized and therefore may reduce cost or complexity, while having the electronic component meet a desired safety rating, such as ASIL D.

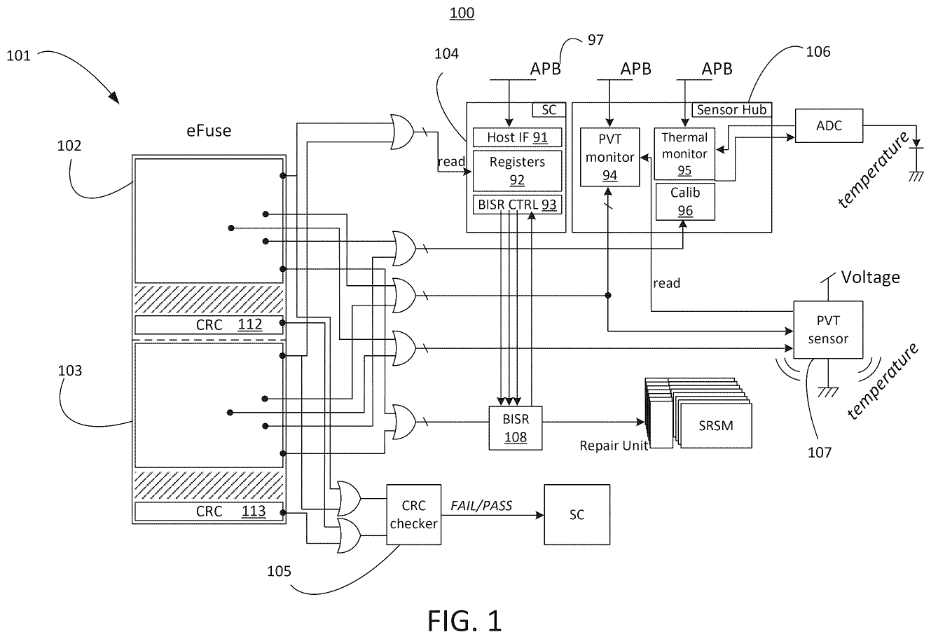

FIG. 1 illustrates example eFuse connectivity associated with a system on a chip (SoC) 100. The eFuse block 101 may include one or more eFuses. The eFuses, such as eFuse 102, may be programmed to permanently change their internal structure when triggered, which may act as a protective mechanism against overcurrent, overvoltage, and other faults. The eFuse block 101 may include eFuse 102 with corresponding CRC checksum 112 and eFuse 103 with corresponding CRC checksum 113. CRC checker 105 may be communicatively connected with eFuse block 101. CRC checker 105 may determine whether there is a fault based on comparison of CRC checksums. eFuse block 101 may be connected with system controller block 104, CRC checker 105, sensor hub 106, PVT sensor 107, or built-in self-repair (BISR 108). eFuses that are stored in flops post device boot and meet ASIL-B (D) integrity using a fault-tolerance technique of triple modular redundancy (TMR) (as may be provided in system controller block 104) may be used to drive the memory or sensors when a respective power domain is powered on. The ASIL-B (D) notation indicates that the ASIL-D integrity may be met by two decomposed ASIL-B requirements. In a first scenario, which may be during boot, CRC checks+BIST may be combined to meet ASIL-D. The boot stage typically occurs immediately after power-on or reset and involves essential initialization processes to bring the system into a functional state. And in second scenario, during mission mode, TMR+BIST may be combined to meet ASIL-D. Mission mode is the state or configuration in which an integrated circuit is operational and executing its primary application tasks in the end-user environment. Mission mode may be defined as the mode of operation of the device when a safety application is running; the eFuses are put in use in mission mode.

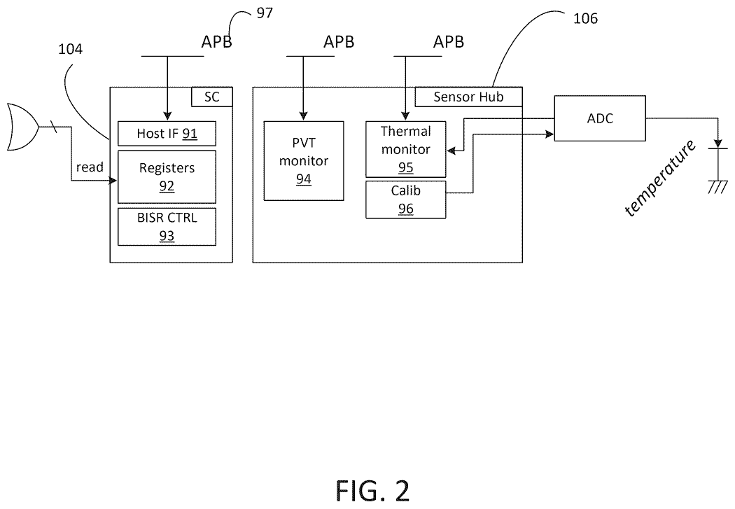

FIG. 2 illustrates an example detailed view of system controller (SC) block 104 and sensor block 106 of SoC 100. SC block 104 may include host interface 91 (Host IF 91), registers 92, or built-in self-repair control 93 (BISR Ctrl 93). Sensor hub 106 may include PVT monitor 94, thermal monitor 95, or calibration 96. With reference to SC block 104, Host IF 91 may provide communication between the system and external host devices while managing data transfer and control signals, registers 91 may store configuration settings and status information, and BISR CTRL 93) may manage self-repair mechanisms. SC 104 may assist with coordination of overall system operations and initialization.

Sensor hub 106 may incorporate multiple monitoring or calibration components, such as a Process, Voltage, Temperature (PVT) monitor 94 that tracks critical operating parameters to ensure reliable operation across different conditions, a thermal monitor 95 for system temperature monitoring and prevention of overheating, or a calibration unit 96 that may handle system calibration procedures and adjust parameters to maintain accuracy. Sensor Hub 106 may serve as a central point for sensor data collection or routing while managing various sensor inputs. Sensor hub 106 and SC block 104 may be interconnected, such as through an Advanced Peripheral Bus 97 (APB 97).

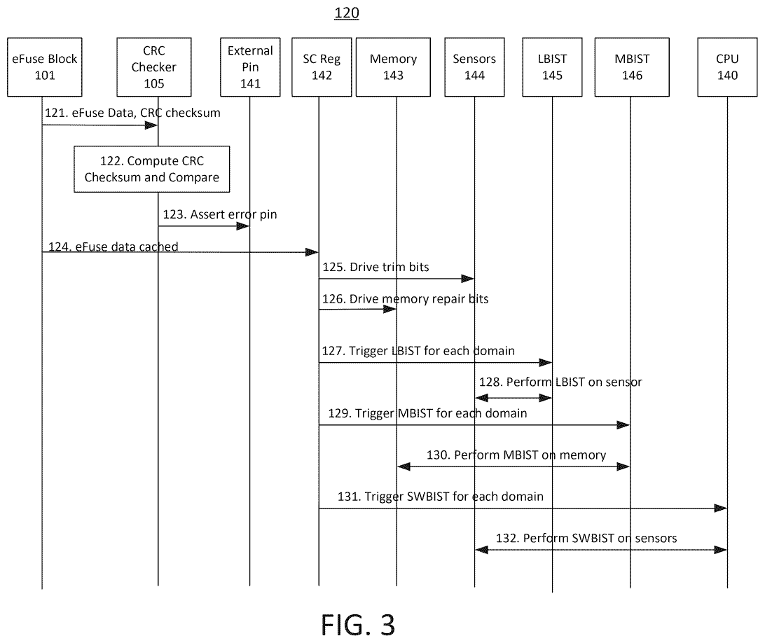

FIG. 3 illustrates an exemplary sequence diagram associated with integrity checks of one or more electronic components. At step 121, eFuse block 101 may send eFuse information to CRC checker 105. The eFuse information may include eFuse 102 data with precomputed eFuse 102 CRC checksum 112 or eFuse 103 data with precomputed eFuse 103 CRC checksum 113. CRC checksum 112 or CRC checksum 113 may be computed on the respective eFuses and stored as part of the respective eFuse 102 and eFuse 103 during a factory programming stage or the like.

At step 122, CRC checker 105 may compute the CRC checksums for eFuse 102 and eFuse 103 based on respective eFuse 102 data and eFuse 103 data. This step 122 may occur at some subsequent time after factory programming (also referred herein as post computed), or the like. CRC checker 105 may compute the CRC checksums for eFuse 102 and eFuse 103 on device boot, therefore for simplicity will be referenced as boot CRC checksums. The boot CRC checksum for eFuse 102 and the boot CRC checksum for eFuse 103 may be compared, by checker 105, with CRC checksum 112 and CRC checksum 113. If an error is detected based on the comparison of step 122, then, at step 123, an indication of error may be sent to external pin 141. Based on the indication of the error, a processor may transmit an indication to shutdown a data flow. Based on the indication of the error, no further data may be received or processed for one or more components. There may be a corresponding alert regarding such shutdown. This CRC check may achieve up to ASIL-B (D) integrity for eFuse 102 and eFuse 103. Shutdown of data flow may include, but is not limited to, stopping the execution of a safety applications when it is determined through the integrity checks (CRC, TMR, BIST, etc.) of the existence of faulty or corrupted eFuses.

At step 124, eFuse information of eFuse block 101 may be cached. At step 125, SC register 142 may drive sensor trim bits with the use of eFuse block 101. At step 126, SC register 142 may drive memory repair bits with the use of eFuse block 101. At step 127, a logic built-in-self-test (LBIST) 145 may be triggered, which may be by SC register 142 after power on. At step 128, LBIST 145 may perform LBIST on sensor 144. In addition, TMR may be used here to ensure integrity of the eFuse storage in registers before they are sent out for being used by sensors or memories. Triple Modular Redundancy (TMR) is a fault tolerant technique for avoiding errors in integrated circuits. The TMR scheme may use three logic blocks performing the same task in tandem with corresponding outputs being compared through majority voters. At step 129, a memory built-in-self-test (MBIST) 146 may be triggered, which may be triggered by SC register 142 after power on. At step 130, MBIST 146 may perform MBIST on memory 143. At step 131, CPU 140 may be triggered to run a software built-in-self-test (SWBIST), which may be triggered by SC register 142 after power on. At step 132, CPU 140 may perform SWBIST on sensor 144. It is contemplated that components of sequence diagram 120 may be on a single device or distributed and may be functional components. It is contemplated, but not shown throughout, based on the comparisons herein that may indicate an error, an error indication may be transmitted to trigger further actions. These further actions may be a display of the error on a display screen, shutdown of a data flow, or restricting access to one or more features of a vehicle or other devices.

Step 125 through step 132 may occur during a mission mode. Use of the BISTs may help achieve up to ASIL-B (D) integrity for the eFuses. As a combination (e.g., CRC checksum and BIST), ASIL-D integrity may be achieved for eFuse block 101 for the use case at device boot or use case in mission mode, among others. In addition, TMR may be used here to ensure integrity of the eFuse storage in registers before they are sent out for being used by sensors or memories. During mission mode, the eFuse block 101 are also driven to each of the memories or sensors during power off and power on domains. In such case, the eFuses that are stored in flops post device boot and meet ASIL-B (D) integrity using triple modular redundancy (TMR) (as shown in SC block 104) may be used to drive the memory or sensors when a respective power domain is powered on. A BIST test may also be re-executed each time a power domain is powered on and hence also meet ASIL-B (D) integrity.

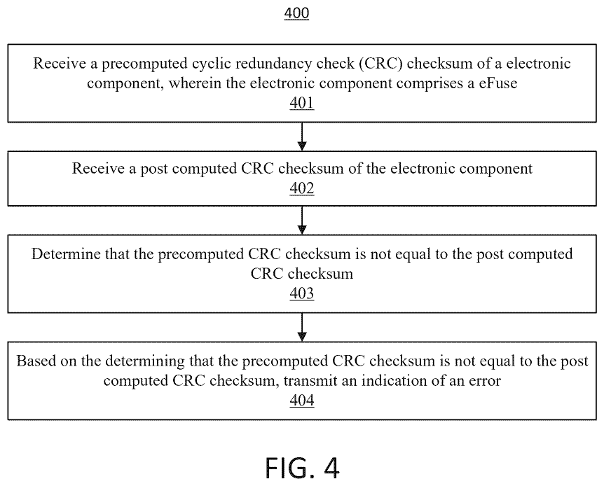

FIG. 4 illustrates an example method 400 for performing hardware integrity checks in electronic components, such as in electronic fuse (eFuse) implementations. The method may be executed by one or more components of SoC 100, such as CRC checker 105. At step 401, the method includes receiving a first precomputed cyclic redundancy check (CRC) checksum of a first electronic component, wherein the first electronic component comprises a first eFuse. The precomputed CRC checksum may be stored directly with the first eFuse during factory programming to maintain a close association between the verification data and the component being verified.

At step 402, a first post computed CRC checksum of the first electronic component may be received. This computation may occur during operational use of the component, such as during device boot-up or mission mode operation.

At step 403, there may be a determination that the first precomputed CRC checksum is not equal to the first post computed CRC checksum. This comparison may serve as an integrity check that can identify potential hardware faults or data corruption. During this step, a hardware CRC checker may perform the verification before the checksums are loaded into on-chip memory of the first electronic component.

At step 404, based on the determination of checksum mismatch of step 403, an indication of an error is transmitted. This error indication triggers several protective actions, may include the shutdown of data flow or the cessation of operation for applications such as autonomous driving systems.

The method can be customized based on the specific requirements of different electronic components and their applications. For instance, in automotive applications, the verification process aligns with various Automotive Safety Integrity Level (ASIL) requirements, adjusting its rigor based on the criticality of the component being verified.

The disclosed subject matter may be directed to functionally safe processing using hardware integrity checks that may comply with Automotive Safety Integrity Level (ASIL). The disclosed subject matter may be used in or with automotive electronic components. Electronic components may be integrated into automobiles, such as an electric vehicle.

Methods, systems, and apparatuses, among other things, as described herein may provide for integrity checks of one or more electronic components. For example, a system may include an eFuse block that includes CRC checksums of one or more eFuses within the eFuse block. The system may include a CRC checker that determines whether pre-calculated CRC checksum matches a subsequently calculated (e.g., during boot-up or mission mode of a device) CRC checksum. The systems, methods, or apparatuses as disclosed herein may be compliant with ASIL, such as ASIL A, B, C, or D. All combinations in this paragraph and the previous paragraphs (including the removal or addition of steps or components) are contemplated in a manner that is consistent with the other portions of the detailed description.

Methods, systems, or apparatuses with regard to fault detection in electronic fuse implementations are disclosed herein. A method may provide for receiving, by a computing device, electronic fuse (eFuse) data and a first cyclic redundancy check (CRC) checksum associated with a first eFuse; computing, by the computing device, a second CRC checksum based on the eFuse data; comparing the first CRC checksum with the second CRC checksum; determining a fault based on the comparing; and transmitting an indication of the fault to an external pin, wherein the indication triggers a shutdown of a data flow. The method may include caching the eFuse data; driving sensor trim bits with the cached eFuse data; or driving memory repair bits with the cached eFuse data. The method may include triggering a logic built-in-self-test (LBIST) on a sensor; triggering a memory built-in-self-test (MBIST) on a memory; or triggering a software built-in-self-test (SWBIST) on the sensor. The method may include performing triple modular redundancy (TMR) checks on registers storing the eFuse data. The eFuse data may include sensor trim data or memory repair information. The computing device may determine the fault during a boot-up or during a mission mode. The first CRC checksum may be computed during a factory programming stage. All combinations (including the removal or addition of steps) in this paragraph and the above paragraphs are contemplated in a manner that is consistent with the other portions of the detailed description.

An apparatus may include an electronic fuse (eFuse) block comprising a first eFuse and a first cyclic redundancy check (CRC) checksum associated with the first eFuse; a CRC checker communicatively connected with the eFuse block; a register block communicatively connected with the eFuse block; a sensor hub communicatively connected with the eFuse block; and a built-in self-repair (BISR) component communicatively connected with the eFuse block. The CRC checker may receive eFuse data from the first eFuse; compute a second CRC checksum based on the eFuse data; compare the first CRC checksum with the second CRC checksum; and transmit an indication of a fault based on the comparing. The register block may perform triple modular redundancy (TMR) checks on registers storing eFuse data. The sensor hub may trigger a logic built-in-self-test (LBIST). The BISR component may trigger a memory built-in-self-test (MBIST). The eFuse block may store sensor trim data. The apparatus may comply with an Automotive Safety Integrity Level (ASIL) standard. All combinations (including the removal or addition of components) in this paragraph and the above paragraphs are contemplated in a manner that is consistent with the other portions of the detailed description.

A system may include an electronic fuse (eFuse) block that includes a register block configured to store eFuse data; a cyclic redundancy check (CRC) checker configured to verify integrity of the eFuse data; and a processor configured to execute instructions to: receive the eFuse data and a first CRC checksum; compute a second CRC checksum based on the eFuse data; compare the first CRC checksum with the second CRC checksum; and determine a fault based on the comparing. All combinations (including the removal or addition of components) in this paragraph and the above paragraphs are contemplated in a manner that is consistent with the other portions of the detailed description.

A reference to an element in the singular is not intended to mean one and only one unless specifically so stated, but rather one or more. For example, “a” module may refer to one or more modules. An element proceeded by “a,” “an,” “the,” or “said” does not, without further constraints, preclude the existence of additional same elements.

Headings and subheadings, if any, are used for convenience only and do not limit the invention. The word exemplary is used to mean serving as an example or illustration. To the extent that the term include, have, or the like is used, such term is intended to be inclusive in a manner similar to the term comprise as comprise is interpreted when employed as a transitional word in a claim. Relational terms such as first and second and the like may be used to distinguish one entity or action from another without necessarily requiring or implying any actual such relationship or order between such entities or actions.

Phrases such as an aspect, the aspect, another aspect, some aspects, one or more aspects, an implementation, the implementation, another implementation, some implementations, one or more implementations, an embodiment, the embodiment, another embodiment, some embodiments, one or more embodiments, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

A phrase “at least one of” preceding a series of items, with the terms “and” or “or” to separate any of the items, modifies the list as a whole, rather than each member of the list. The phrase “at least one of” does not require selection of at least one item; rather, the phrase allows a meaning that includes at least one of any one of the items, and/or at least one of any combination of the items, and/or at least one of each of the items. By way of example, each of the phrases “at least one of A, B, and C” or “at least one of A, B, or C” refers to only A, only B, or only C; any combination of A, B, and C; and/or at least one of each of A, B, and C.

It is understood that the specific order or hierarchy of steps, operations, or processes disclosed is an illustration of exemplary approaches. Unless explicitly stated otherwise, it is understood that the specific order or hierarchy of steps, operations, or processes may be performed in different order. Some of the steps, operations, or processes may be performed simultaneously. The accompanying method claims, if any, present elements of the various steps, operations or processes in a sample order, and are not meant to be limited to the specific order or hierarchy presented. These may be performed in serial, linearly, in parallel or in different order. It should be understood that the described instructions, operations, or systems can generally be integrated together in a single software/hardware product or packaged into multiple software/hardware products.

In one aspect, a term coupled or the like may refer to being directly coupled. In another aspect, a term coupled or the like may refer to being indirectly coupled.

Terms such as top, bottom, front, rear, side, horizontal, vertical, and the like refer to an arbitrary frame of reference, rather than to the ordinary gravitational frame of reference. Thus, such a term may extend upwardly, downwardly, diagonally, or horizontally in a gravitational frame of reference.

The disclosure is provided to enable any person skilled in the art to practice the various aspects described herein. In some instances, well-known structures and components are shown in block diagram form in order to avoid obscuring the concepts of the subject technology. The disclosure provides various examples of the subject technology, and the subject technology is not limited to these examples. Various modifications to these aspects will be readily apparent to those skilled in the art, and the principles described herein may be applied to other aspects.

All structural and functional equivalents to the elements of the various aspects described throughout the disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112 (f), unless the element is expressly recited using the phrase “means for” or, in the case of a method claim, the element is recited using the phrase “step for”.

Those of skill in the art would appreciate that the various illustrative blocks, modules, elements, components, methods, and algorithms described herein may be implemented as hardware, electronic hardware, computer software, or combinations thereof. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

The title, background, brief description of the drawings, abstract, and drawings are hereby incorporated into the disclosure and are provided as illustrative examples of the disclosure, not as restrictive descriptions. It is submitted with the understanding that they will not be used to limit the scope or meaning of the claims. In addition, in the detailed description, it can be seen that the description provides illustrative examples and the various features are grouped together in various implementations for the purpose of streamlining the disclosure. The method of disclosure is not to be interpreted as reflecting an intention that the claimed subject matter requires more features than are expressly recited in each claim. Rather, as the claims reflect, inventive subject matter lies in less than all features of a single disclosed configuration or operation. The claims are hereby incorporated into the detailed description, with each claim standing on its own as a separately claimed subject matter.

The claims are not intended to be limited to the aspects described herein, but are to be accorded the full scope consistent with the language of the claims and to encompass all legal equivalents. Notwithstanding, none of the claims are intended to embrace subject matter that fails to satisfy the requirements of the applicable patent law, nor should they be interpreted in such a way.

What is claimed is:

1. A method for hardware integrity checks, the method comprising:
receiving a first precomputed cyclic redundancy check (CRC) checksum of a first electronic component, wherein the first electronic component comprises a first eFuse;
receiving a first post computed CRC checksum of the first electronic component;
determining that the first precomputed CRC checksum is not equal to the first post computed CRC checksum; and
based on the determining that the first precomputed CRC checksum is not equal to the first post computed CRC checksum, transmitting an indication of an error.

2. The method of claim 1, further comprising:
receiving a second precomputed CRC checksum of a second electronic component, wherein the second electronic component comprises a second eFuse;
receiving a second post computed CRC checksum of the second electronic component;
determining that the second precomputed CRC checksum is not equal to the second post computed CRC checksum; and
based on the determining that the second precomputed CRC checksum is not equal to the second post computed CRC checksum, transmitting an indication of a second error.

3. The method of claim 1, further comprising transmitting, based on the indication of the error, an indication to cease operation of one or more applications.

4. The method of claim 3, wherein the one or more applications comprise an autonomous driving application.

5. The method of claim 1, wherein the first electronic component is integrated into an electric vehicle.

6. The method of claim 1, wherein the precomputed CRC checksum is stored with the first eFuse.

7. The method of claim 1, wherein the first precomputed CRC checksum was verified by using a hardware CRC checker before loading the first precomputed CRC checksum to on-chip memory of the first electronic component.

8. The method of claim 1, wherein the first electronic component uses, during boot, a built-in-self-test and a CRC check.

9. The method of claim 1, wherein the first electronic component uses, during mission mode, a built-in-self-test and triple modular redundancy.

10. The method of claim 1, wherein the indication of the error causes a shutdown of a data flow.

11. A system comprising:
a first eFuse, which comprises a cyclic redundancy check (CRC) checksum of the first eFuse; and
a second eFuse, which comprises a CRC checksum of the second eFuse.

12. The system of claim 11, wherein the system is integrated into an electric vehicle.

13. The system of claim 11, wherein the system is compliant with Automotive Safety Integrity Level (ASIL) B or ASIL D.

14. A method for hardware integrity checks, the method comprising:
receiving a first precomputed cyclic redundancy check (CRC) checksum of a first electronic component, wherein the first electronic component comprises a first eFuse;
receiving a first post computed CRC checksum of the first electronic component;
determining whether there is a first fault based on a mismatch of the first precomputed CRC checksum and the first post computed CRC checksum;
determining whether there is a second fault based on a safety mechanism comprising a triple modular redundancy (TMR) or built-in-self-test (BIST); and
based on determining that there is a first fault or a second fault, transmitting an indication of an error.

15. The method of claim 14, wherein the BIST comprises a logic built-in-self-test.

16. The method of claim 14, wherein the BIST comprises a memory built-in-self-test.

17. The method of claim 14, wherein the BIST comprises a software built-in-self-test.

18. The method of claim 14, wherein the precomputed CRC checksum is stored with the first eFuse.

19. The method of claim 14, wherein the first precomputed CRC checksum was verified by using a hardware CRC checker before loading the first precomputed CRC checksum to on-chip memory of the first electronic component.

20. The method of claim 14, wherein the indication of the error causes a shutdown of a data flow.
